(19) United States
(12) Patent Application Publication
(10) Pub. No.: US 2005/0127516 A1
(43) Pub. Date: Jun. 16, 2005

(54) Small viatops for thick copper connectors

(76) Inventors: Betty Shu Mercer, Plano, TX (US); Alec J. Morton, Plano, TX (US); Byron Lovell Williams, Plano, TX (US); Laurinda W. Ng, Plano, TX (US); C. Matthew Thompson, Highland Village, TX (US); Der-E Jan, Plano, TX (US); Sunny Kam Lee, Garland, TX (US); Phuong-Lan Thi Tran, Frisco, TX (US)

Correspondence Address: TEXAS INSTRUMENTS INCORPORATED, P O BOX 655474, M/S 3999, DALLAS, TX, 75265, US

(21) Appl. No.: 10/735,374

(22) Filed: Dec. 12, 2003

(51) Int. Cl. H01L 21/44; H01L 29/40

(52) U.S. Cl. 257/763; 438/683; 257/762; 438/687; 257/774; 438/629

(57) ABSTRACT

The present invention relates to integrated circuits comprising a protective overcoat and thick copper connectors. According to one aspect of the inventions, vias in the protective overcoat are substantially filled with tungsten plugs, or plugs of another metal with a relatively low coefficient of thermal expansion. According to another aspect of the invention, large vias in the protective overcoat are replaced with arrays of smaller vias. The invention reduces the likelihood of device failures during temperature cycling tests. Also, the invention allows for smaller vias in the protective overcoat and removal of interconnect functions to the thick copper layer.

### FIELD OF THE INVENTION

The present invention relates generally to the field of integrated circuit manufacturing, and more particularly relates to devices with thick copper leads.

### BACKGROUND OF THE INVENTION

For integrated circuit power devices that experience high currents, e.g., currents above about 100 milliamps, thick copper is desirable for forming low resistance leads. Where the currents are above about 1 amp, and especially when the currents are above about 10 amps, thick copper can be considered essential. Thick copper allows the higher currents to be carried in a considerably smaller area than would be required with other metal layers. Thick copper is formed over a protective overcoat. The protective overcoat provides physical, chemical, and ion protection for underlying structures.

According to a standard process for forming thick copper leads, the protective overcoat is lithographically patterned to expose the bond pads. The bond pads are typically about 60 μm to about 100 μm square. A conductive barrier layer and a copper seed layer are sputter deposited over the protective overcoat and within the openings patterned through the overcoat. A resist coating is then formed and patterned to cover the copper seed layer everywhere except where thick copper is desired. Thick copper is plated on. After plating, the resist is removed and the barrier layer and the seed layer etched away where they were covered by the resist. This process is generally effective, but the resulting products in some cases may show a non-negligible failure rate during temperature cycling tests.

### SUMMARY OF THE INVENTION

The following presents a simplified summary in order to provide a basic understanding of some aspects of the invention. This summary is not an extensive overview of the invention. It is intended neither to identify key or critical elements of the invention nor to delineate the scope of the invention. Rather, the primary purpose of this summary is to present some concepts of the invention in a simplified form as a prelude to the more detailed description that is presented later.

One aspect of the invention relates to an integrated circuit comprising a protective overcoat and thick copper connectors. Vias in the protective overcoat are substantially filled with tungsten plugs, or plugs of another metal with a relatively low coefficient of thermal expansion. The plugs provide electrical contact between the thick copper and the underlying metallization layer. Tungsten has a much better thermal expansion coefficient match than copper with typical protective overcoat materials, such as silicon oxynitride and silicon nitride. Using a metal with a lower coefficient of thermal expansion in the vias and displacing all or most of the copper above the protective overcoat reduces the likelihood of device failures during temperature cycling tests. In addition, the tungsten plugs can be made much smaller than the prior art, and such smaller plug dimensions have been found to avoid problems associated with the prior art during temperature cycling.

Another aspect of the invention relates to an integrated circuit comprising a protective overcoat and thick copper connectors wherein large individual vias in the protective overcoat are replaced by arrays of smaller vias. Using smaller vias also reduces the likelihood of device failures during temperature cycling tests.

A further aspect of the invention relates to an integrated circuit comprising a protective overcoat and thick copper leads wherein the protective overcoat includes vias having a critical dimension of 2.0 μm or less across. Vias of this size are too small for the seeding and plating operations typically used to form thick copper connectors. The vias can be filled with copper using a process adapted for forming copper metallization layers or can be filled with another metal, such as tungsten. These smaller vias allow contacts to be formed with small or densely packed features, whereby thick copper can be used for interconnections. The smaller vias also permit underlying metallization routing to be smaller (more narrow), thereby allowing more flexibility in the underlying metallization routing. In some cases, this allows an entire layer of metallization to be eliminated.

To the accomplishment of the foregoing and related ends, the following description and annexed drawings set forth in detail certain illustrative aspects and implementations of the invention. These are indicative of but a few of the various ways in which the principles of the invention may be employed. Other aspects, advantages and novel features of the invention will become apparent from the following detailed description of the invention when considered in conjunction with the drawings.

### BRIEF DESCRIPTION OF THE DRAWINGS

FIG. 1 is a flow chart illustrating a process according to one aspect of the present invention.

FIG. 2 is a cross-sectional schematic illustration of a semiconductor substrate with an upper metallization layer.

FIG. 3 is a cross-sectional schematic illustration of the semiconductor substrate of FIG. 2 after forming and patterning a protective overcoat.

FIG. 4 is a cross-sectional schematic illustration of the semiconductor substrate of FIG. 3 depositing a barrier layer and substantially filling the vias with a metal.

FIG. 5 is a cross-sectional schematic illustration of the semiconductor substrate of FIG. 4 after chemical mechanical polishing.

FIG. 6 is a cross-sectional schematic illustration of the semiconductor substrate of FIG. 5 after depositing a copper seed layer and forming and patterning a thick resist layer over the copper seed layer.

FIG. 7 is a cross-sectional schematic illustration of the semiconductor substrate of FIG. 6 after plating on copper, removing the thick resist, and etching.

FIG. 8 is a cross-sectional schematic illustration of a semiconductor substrate processed in a similar manner to the semiconductor substrate shown FIG. 7, but without chemical mechanical polishing.

### DETAILED DESCRIPTION OF THE INVENTION

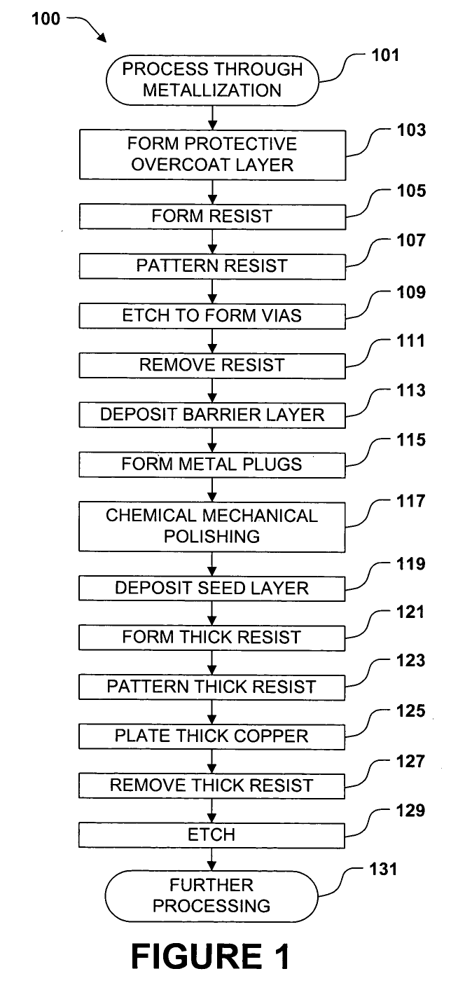

The present invention will now be described with reference to the attached drawings, wherein like reference numerals are used to refer to like elements throughout. FIG. 1 is a flow chart of an exemplary process 100 according to one aspect of the present invention. Although the exemplary method 100 and variations thereof are described below as a series of acts, the present invention is not limited by the specific ordering of the acts. For example, some acts may occur in different orders and/or concurrently with other acts or events apart from those illustrated and/or described herein, in accordance with the invention. In addition, not all illustrated steps may be required to implement a methodology in accordance with the present invention.

It should be appreciated that the term via top, as used in the present disclosure, refers to the vias within the protective overcoat that connect between the top level of metallization and the thick copper overlying the protective overcoat, as will be more fully appreciated below.

The process 100 begins with act 101, providing a semiconductor substrate processed through formation of a metallization layer.

A semiconductor substrate comprises a semiconductor, typically silicon. Other examples of semiconductors include GaAs and InP. In addition to a semiconductor, a semiconductor substrate may include various device elements therein and/or layers thereon. These can include metal layers, barrier layers, dielectric layers, device structures, including silicon gates, word lines, source regions, drain regions, bit lines, bases emitters, collectors, conductive lines, conductive vias, etc.

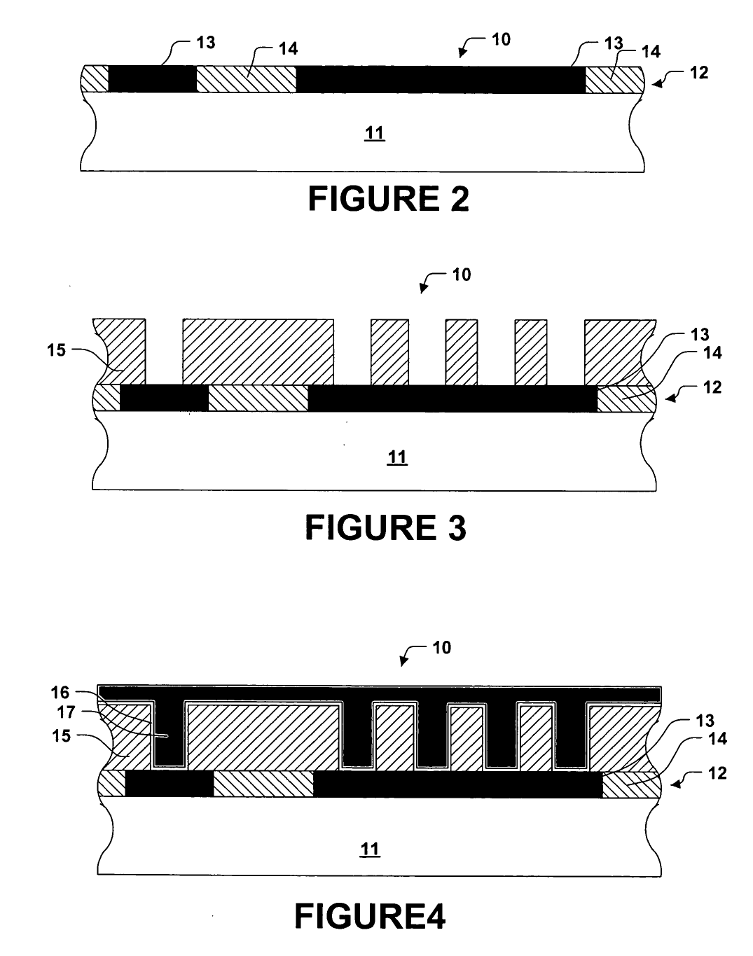

FIG. 2 provides a schematic illustration of an exemplary semiconductor substrate 10 processed through formation of a metallization layer. The substrate 10 includes a semiconductor substrate 11 and a topmost metallization layer 12. In addition to device elements, the substrate 11 may include one or more metallization layers that are not illustrated. A metallization layer includes an inter-level dielectric and a metal. The metal forms conductive lines and, through vias formed in the inter-level dielectric, contacts with underlying structures. The metallization layer 12 includes a metal 13 and an inter-level dielectric 14. In one embodiment, the metal 13 is aluminum. In another embodiment, the metal 13 is copper: The metallization layer 12 may contain one or multiple layers of metallization, as may be appreciated.

Act 103 of FIG. 1 is forming a protective overcoat layer. A protective overcoat is an insulating layer that provides electrical isolation and mechanical protection for underlying structures. Preferably, it also provides chemical and ion protection. The protective overcoat may comprise one or more layers. Typical layer materials include silicon nitride, silicon oxynitride, silicon oxide, PSG (Phospho-Silicate Glass), organic polymers such as polyimide, and other materials. Silicon nitride is preferred for its strength, but silicon oxynitride is often used in its place where transparency is needed, for example, to allow UV memory erase. Preferably the overall thickness of the protective overcoat is from about 0.5 to about 2.0 μm, more preferable from about 0.8 to about 1.5 μm.

Acts 105, 107, 109, and 111 comprise an exemplary lithographic process used to pattern the protective overcoat. Lithography refers to processes for pattern transfer between various media. Act 105 is forming a radiation sensitive resist coating. Act 107 is patterning the resist by selectively exposing the resist through a mask. The exposed areas of the coating become either more or less soluble than the unexposed areas, depending on the type of resist. A solvent developer is used to remove the less soluble areas leaving the patterned resist.

Act 109 is etching the protective overcoat using the patterned resist as a mask to transfer the pattern to the protective overcoat. Etch processes include plasma etching, reactive ion etching, wet etching, and combinations thereof, but plasma etching is preferred. Preferably, the etch process is highly anisotropic and gives vertical sidewalls to the patterned features. Act 111 is removing the resist.

FIG. 3 schematically illustrates a cross-section of the substrate 10 after forming and patterning a protective overcoat 15. On the right, four vias are shown connecting to a single metal portion (that will be associated with a bond pad) in the metallization layer 12. This illustrates one aspect of the invention wherein an array of vias in the protective overcoat layer connect to a single metal portion and consequently a single bond pad thereover. The array of vias preferably have a critical dimension from about 0.5 μm to about 15 μm, more preferably from about 5 μm to about 9 μm. In this context, although an array is generally a regular pattern, there is no requirement that the vias be regularly spaced or placed in any particular pattern. When filled with metal, an array of smaller vias in a protective overcoat will create lower or less destructive thermal stresses than a single large via. In this schematic illustration, four vias span a metal portion. In practice, a much larger number of vias may be used to span a metal portion, which is typically from about 60 μm to about 100 μm square.

Another aspect of the invention is that individual vias can have a critical dimension of about 2.0 μm or less, or even about 1.0 μm or less. These smaller vias can be used to make contacts with small features. In prior art process, vias for thick copper connectors were practically limited to a critical dimension of about 2.4 μm due to the difficulty of obtaining good coverage of the sputter-deposited copper seed layer in smaller vias. Whereas thick copper has historically been used for wide, high-current leads, the present invention allows the thick copper to also provide logic interconnections between device elements within an integrated circuit. In some cases, this can eliminate the need for an entire metallization layer.

After forming and patterning the protective overcoat, the semiconductor substrate is covered by a barrier layer 16 (FIG. 4) with Act 113 of FIG. 1. The barrier layer 16 is conductive and limits copper diffusion. Additional functions of the barrier layer can include providing low electrical resistance between the upper metallization layer and the metal that fills the vias and providing good adhesion between these metals. When the vias are filled with a metal other than copper, the barrier layer may not be needed, at least not at this stage, although a barrier layer is generally used at least to improve adhesion with the metal that fills the plugs. The barrier layer 16 can be a refractory metal such as titanium, tungsten, chromium, molybdenum, or an alloy thereof. In a preferred embodiment, the barrier layer is TiW, however, for a copper type system a typical conductive copper barrier such as TiN or TaN may be employed. The thickness of the barrier layer is preferable from about 0.1 to about 0.5 μm, more preferably from about 0.2 to about 0.3 μm. The barrier layer can be formed by any suitable method including, for example, physical vapor deposition, chemical vapor deposition, electroless plating, electroplating, or sputtering. Generally, chemical or physical vapor deposition is used is allow uniform coating of small vias with steep sidewalls. Although a barrier layer 16 is described in present example, in another option such barrier layer may be eliminated.

Act 1 15 is forming a metal layer 17 (FIG. 4) over the barrier layer 16. The metal substantially fills at least the smaller vias. Preferably, the metal is deposited to a thickness from about 0.4 μm to about 1.5 μm, more preferably from about 0.5 μm to about 0.8 μm. If the metal layer is too thick, it may tend to delaminate. While the metal layer 17 may be deposited by any suitable process, or combination of processes, such as the process recited above with respect to forming the barrier layer. It is preferred that the process forms the metal layer on the sidewalls of the vias whereby the vias are substantially filled by depositing a layer thickness equal to half the critical dimension of the vias. For metals such as tungsten, chemical vapor deposition is preferred. For copper, it is generally preferable to form a seed layer by chemical or physical vapor deposition and then complete the deposition with electroless plating or electroplating. Subtantially filled means that the barrier layer and the metal layer together occupy at least about 80% of the via volume. In one embodiment, the metal has a coefficient of thermal expansion less than or equal to about 8 ppm/° C. and is preferably tungsten.

From time to time throughout this specification and the claims that follow, a layer or structure may be described as being of a substance such as “aluminum”, “tungsten”, “copper”, “silicon nitride”, etc. These description are to be understood in context and as they are used in the semiconductor manufacturing industry. For example, in the semiconductor industry, when a metallization layer is described as being aluminum, it is understood that the metal of the layer comprises pure aluminum as a principle component, but the pure aluminum may be, and typically is, alloyed, doped, or otherwise impure. As another example, silicon nitride may be a silicon rich silicon nitride or an oxygen rich silicon nitride. Silicon nitride may contain some oxygen, but not so much that the material's dielectric constant is substantially different from that of high purity stoichiometric silicon nitride.

FIG. 4 illustrates the substrate 10 with a barrier layer 16 and a metal layer 17. The metal layer 17 substantially fills all the illustrated vias, but it is noted that the protective overcoat 15 may also contain large vias and that these larger vias may be only partially filled by the metal layer 17.

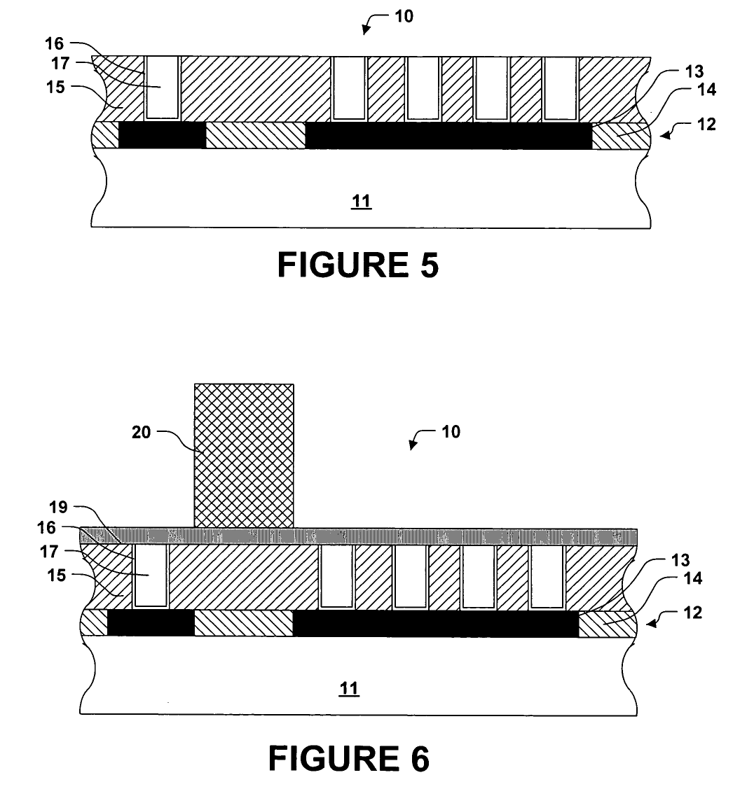

In FIG. 5, the portions of the barrier layer 16 and the metal layer 17 above the protective overcoat 15 have been removed by Act 117 of FIG. 1, chemical mechanical polishing. The advantage of chemical mechanical polishing at this stage is that subsequent steps may be carried out with equipment in place for carrying out the prior art process including sputter deposition of a barrier layer and copper seed layer followed by formation of a thick patterned resist and plating of thick copper. In the long run, however, it may be more economical to skip chemical mechanical polishing at this stage. If chemical mechanical polishing is skipped, no further barrier layer is required. If the metal used to form the metal plugs is copper, then no further copper seed layer is required.

Returning to the Process 100, Act 119 is depositing a seed layer. Where chemical mechanical polishing 117 has been used, the seed layer also includes a conductive barrier layer to prevent copper from diffusing into the protective overcoat. The uppermost portion of the seed layer is generally copper. The copper portion is generally from about 0.1 μm to about 0.5 μm thick, more preferably from about 0.2 μm to about 0.3 μm thick. The seed layer can be deposited by any suitable means including, for example, sputter deposition. Where the metal substantially filling the vias is copper, seed layer deposition 119 is unnecessary. Act 121 is forming a thick resist over the seed layer. The thick resist will define the shape of the thick copper. Generally, the thick resist is deposited to a thickness greater than the desired thickness for the copper layer. For example, a 25 μm thick resist can be used. Act 123 is patterning the thick resist. FIG. 6 illustrates the substrate 10 with a seed layer 19 and a patterned thick resist 20. It should be appreciated that seed layer 19 in the present example is illustrated as a single layer, however, multi-layer seed layers (e.g., TiW and copper) may be employed and are contemplated by the present invention.

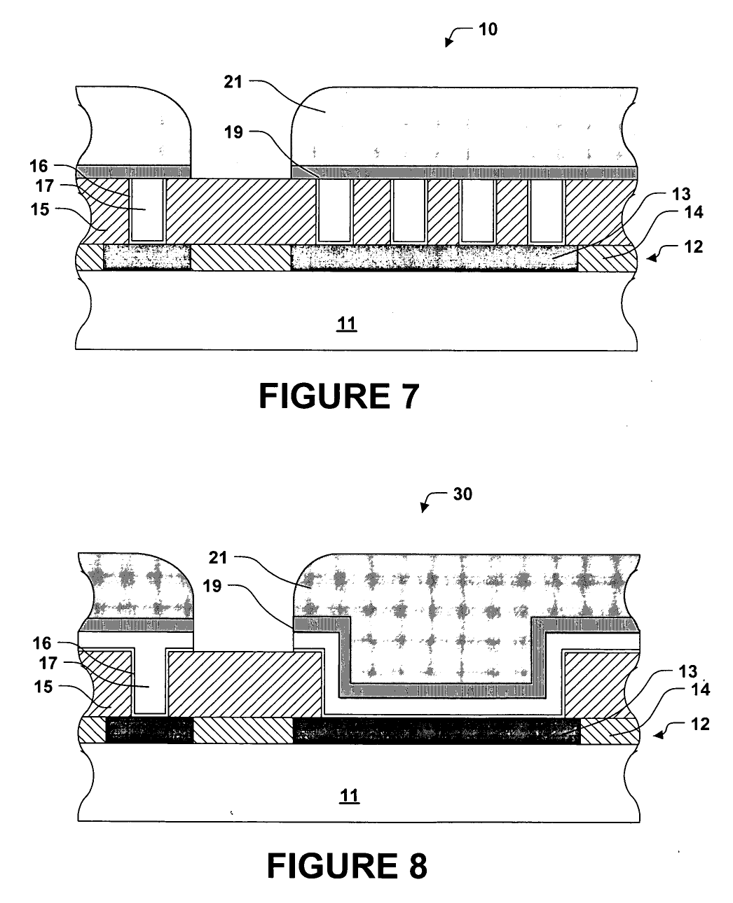

Act 125 is plating to form a thick copper layer. Either electrical or electroless plating can be used. A thick copper layer is at least about 5 μm thick, preferable from about 6 μm to about 15 μm thick. After forming the thick copper, the thick resist is removed by Act 127. Act 129 is etching to remove the barrier layer and the seed layer where they are not covered by the thick copper. Where chemical mechanical polishing 117 is not used, etching at 129 also removes the unwanted metal (that would otherwise short various interconnections together). FIG. 7 illustrates the substrate 10 with a thick copper layer 21 after etching 129. A continuous portion of the thick copper layer 21 contacts all the vias in the array contacting the bond pad on the right.

FIG. 8 illustrates a substrate 30 that has undergone the process 100 without chemical mechanical polishing 117. The metal 17 partially overlays the protective overcoat 15. FIG. 8 also illustrates a result that can be obtained when vias of varying size are used. The smaller via on the left is substantially filled by the metal 17, whereas the via on the right is only partially filled with the metal 17. For example, the via on the left might have a critical dimension of about 1.0 μm, the via on the right might have a critical dimension of about 5 μm, and the metal might be deposited to a thickness of about 0.5 μm. The metal substantially fills only those vias with a critical dimension less than or equal to about two times the metal layer thickness.

Tungsten has a higher resistance than copper. Nevertheless, measurements have shown that for vias in the 5.0 to 9.0 μm range a tungsten layer from about 0.5 μm to about 0.8 μm thick results in vias having a lower electrical resistance than vias filled with copper according to the prior art process.

Where one or more of the metallization layers, for example metallization layer 12, uses copper metal, it may be desirable to use copper for the metal layer 17. In the resulting structure, the vias are filled with copper plugs as they are in the prior art thick copper process. A significant difference, however, is the manner in which the copper plugs are formed. According to the present invention, the copper plugs are formed as they would be in a damascene process. Generally this means that a copper seed layer will be formed by chemical or physical vapor deposition. In any case, the copper plugs can conveniently be formed by processes and equipment used to form underlying copper metallization layers. Copper plating to fill the vias can be combined with copper plating to form the thick copper layer.

In particular, one advantage associated with a copper system is that after filling the via tops with copper as illustrated, for example, in FIG. 4, the copper metal (layer 17) overlying the protective overcoat 15 may be employed as a seed layer for the thick copper to be formed thereover. In such an instance, the planarization of FIG. 5 is skipped and thick copper formation occurs and is subsequently patterned, for example, as illustrated in FIG. 8.

Processes of the present invention are generally useful in reducing device failures due to thermal stresses associated with thick copper layers. Processes of the invention can also result in simplified structures. Historically, thick copper has been used to form leads to bond pads. The present invention provides small copper vias that are useful in forming interconnection between locations within the core of an integrated circuit. These interconnection are normally provided exclusively by metallization layers. Forming some of these connections in the thick copper layer can, in some cases, eliminate the need for an entire metallization layer.

Although the invention has been shown and described with respect to a certain aspect or various aspects, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several aspects of the invention, such feature may be combined with one or more other features of the other aspects as may be desired and advantageous for any given or particular application. Furthermore, to the extent that the term “includes” is used in either the detailed description or the claims, such term is intended to be inclusive in a manner similar to the term “comprising.”

1. An integrated circuit, comprising:
a semiconductor substrate comprising device elements and one or more metallization layers interconnecting the device elements and having an uppermost layer;
a protective overcoat formed over the metallization layers, the protective overcoat having vias through it;
tungsten plugs substantially filling the vias and connecting to the uppermost layer; and
thick copper formed over the protective overcoat and forming connections to the tungsten plugs.

2. The integrated circuit of claim 1, wherein the uppermost layer is an aluminum metallization layer.

3. The integrated circuit of claim 1, wherein the protective overcoat comprises one or more layers selected from the group consisting of silicon oxynitride layers, silicon oxide layers and silicon nitride layers.

4. The integrated circuit of claim 1, wherein the vias have a critical dimension of about 2 μm or less.

5. The integrated circuit of claim 4, further comprising larger vias having a critical dimension of about 5 μm or greater, wherein tungsten forms a layer within the larger vias.

6. The integrated circuit of claim 1, wherein the vias have a critical dimension of about 1.0 μm or less.

7. The integrated circuit of claim 1, wherein the thick copper forms interconnections between device elements within the integrated circuit.

8. A method of manufacturing an integrated circuit, comprising:
forming a semiconductor substrate comprising device elements;
forming one or more metallization layers over the device elements, the one or more metallization layers interconnecting the device elements and having an uppermost layer;
forming a protective overcoat layer over the uppermost layer;
patterning vias through the protective overcoat layer to selectively expose the uppermost metallization layer;
substantially filling the vias with a metal having a coefficient of thermal expansion less than or equal to about 8 ppm/° C to form metal plugs;
forming a seed layer over the substrate;
forming a patterned resist coating over the seed layer, wherein the pattern exposes the seed layer over the metal plugs;
plating from the seed layer to form thick copper connections to the metal plugs.

9. The method of claim 8, wherein the vias are patterned with an anisotropic dry etch process, whereby the vias have steep walls.

10. The method of claim 8 wherein the thick copper connections comprise interconnections between device elements within the integrated circuit.

11. The method of claim 8 wherein the uppermost metallization layer is an aluminum metal layer.

12. The method of claim 8, wherein the metal is tungsten.

13. The method of claim 8, wherein the vias have critical dimensions of about 2 μm or less.

14. The method of claim 13, wherein patterning further comprises patterning larger vias having critical dimensions of about 5 μm or greater.

15. The method of claim 8, wherein the protective overcoat comprises one or more layers selected from the group consisting of silicon oxynitride layers, silicon oxide layers and silicon nitride layers.

16. An integrated circuit, comprising:
a semiconductor substrate comprising device elements and one or more metallization layers interconnecting the device elements, the one or more metallization layers having an uppermost layer, the uppermost layer comprising bond pads;
a protective overcoat formed over the metal layers, the protective overcoat having vias through it, wherein arrays of vias are formed over individual bond pads;
metal plugs substantially filling the vias and connecting to the bond pads; and
thick copper connections to the metal plugs.

17. The integrated circuit of claim 16, wherein the metal plugs are copper plugs.

18. The integrated circuit of claim 16, wherein the vias have a critical dimension of about 2 μm or less.

19. The integrated circuit of claim 16, wherein the metal plugs have a coefficient of thermal expansion less than or equal to about 8 ppm/° C.

20. The integrated circuit of claim 16, wherein the metal plugs are tungsten plugs.

21. The integrated circuit of claim 16, wherein the uppermost layer is an aluminum metallization layer.

22. The integrated circuit of claim 16, wherein the protective overcoat comprises one or more layers selected from the group consisting of silicon oxynitride layers, silicon oxide layers and silicon nitride layers.

23. The integrated circuit of claim 16, wherein the thick copper connections comprise interconnections between device elements within the integrated circuit.

24. A method of forming copper connectors on a semiconductor device comprising:
forming a semiconductor substrate comprising device elements;
forming one or more metallization layers over the devices elements, the one or more metallization layers interconnecting the device elements and having an uppermost layer that is a copper metallization layer;
forming a protective overcoat layer;
patterning the protective overcoat layer to form vias having a critical dimension of 2.0 μm or less across;
substantially filling the vias with a metal to form metal plugs;
electroplating thick copper connections to the metal plugs.

25. The method of claim 24, wherein the metal is copper.

26. The method of claim 25, wherein the metal is formed in the vias and overlies the protective overcoat, further comprising using the copper metal overlying the protective overcoat as a seed layer for the electroplating of the thick copper connections.

27. The method of claim 24, wherein the metal is tungsten.

28. The method of claim 24, wherein the metal has a coefficient of thermal expansion less than or equal to about 8 ppm/° C.

29. The method of claim 24, wherein the thick copper connections comprise interconnections between device elements within the integrated circuit.

30. An integrated circuit, comprising:
a semiconductor substrate comprising device elements and one or more aluminum metal layers interconnecting the device elements, the one or more aluminum metal layers having an uppermost layer;
a protective overcoat formed over the metal layers, the protective overcoat having vias through it;
metal plugs filling the vias and connecting to the uppermost layer; and
thick copper connections to the metal plugs;
wherein the thick copper connections comprise interconnections between device elements within the integrated circuit.

31. The integrated circuit of claim 30, wherein the metal plugs are formed of a metal having a coefficient of thermal expansion less than or equal to about 8 ppm/° C.

32. The integrated circuit of claim 30, wherein the metal plugs are formed of tungsten.
